(19) United States
(12) Patent Application Publication
(10) Pub. No.: US 2007/0295266 A1
(43) Pub. Date: Dec. 27, 2007

(54) Method for Synthesizing Semiconductor Quantom Dots

(75) Inventors: Jin-kyu Lee, Seoul (KR); Jae-il Kim, Seoul (KR)

Correspondence Address: VENABLE LLP, P.O. BOX 34385, WASHINGTON, DC, 20043-9998, US

(73) Assignee: NANOSQUARE CO. LTD., SEOUL (KR)

(21) Appl. No.: 11/792,930

(22) PCT Filed: Dec. 13, 2005
(86) PCT No.: PCT/KR05/04263

§ 371 Date: Jun. 13, 2007

(30) Foreign Application Priority Data
Dec. 13, 2004 (KR) 10-2004-0105109
Oct. 7, 2005 (KR) 10-2005-0094417

(51) Int. Cl. C30B 13/02

(52) U.S. Cl. 117/53

(57) ABSTRACT

The present invention relates to a method for synthesizing high luminescence semiconductor quantum dots with a core-shell structure in a short time in large quantity. Using the method of synthesizing the quantum dots in accordance with the present invention, a large quantity of quantum dots can be economically synthesized in a rapid time without an explosion. And, the present invention can be applied to the fields employing various luminous materials since the luminous semiconductor quantum dots synthesized by the present invention has a high luminous efficiency and they can emit a light at various wavelengths in the whole range of a visible ray. And also, the present invention can be applied to a light emission device, a single electron transistor, a solar cell photo-sensitizer material and a bio-labelling tag since it is excellently stable.

### TECHNICAL FIELD

The present invention relates to a method for systhesizing semiconductor quantum dots; and, more particularly, to a method for synthesizing a plurality of high luminescence semiconductor quantum dots with a core-shell structure for a short time.

### BACKGROUND ART

As a size of a semiconductor becomes smaller than a predetermined scale, there can be observed a quantum size effect, i.e., a phenomenon that a luminescence wavelength is changed based on the size of the semiconductor.

Generally, in a high temperature, if a group II metallic precursor and a group IV chalcogenide precursor are added into a solvent such as a tri-n-octylphosphine oxide (hereinafter, referred to TOPO), II-IV group metallic chalcogenide (CdS, CdSe, CdTe, ZnS, ZnSe, ZnTe) semiconductor quantum dots can be obtained.

A cadmium chalcogenide quantum dot is obtained by above described method such as “The High Temperature Pyrolysis” researched by C. B. Murrary, D. J. Norris, and M. G. Bawendi, published in J. Am. Chem. Soc. 1993, 115, 8706-8715. After The High Temperature is known, many research groups have synthezied the cadmium chalcogenide quantum dots and have studied an optical property thereof by using the same method or slightly modified methods.

Such quantum dots have a long alkyl chain (organic ligand) on a surface. This is a result that a solvent or an additive used under a condition for synthesizing the quantum dots adheres to the surface of the quantum dots in order to stabilize the quantum dots. This long alkyl chain adhered at the surface may improve a dispersion property in the organic solvent and, thus, the quantum dots can be applied to various technical fields. Practically, a study using this material has been actively pursued in technical fields based on an organic solvent among technical fields, which requires any light emitting material, such as a light emission device, a solar cell, a laser or the like.

In order to allow the semiconductor quantum dots to be used in various solvents, it is required that the organic ligand existing on the surface of the quantum dots be exchanged with other organic ligand having a functional group to allow the dispersion in various solvents. This process is referred to as a surface ligand exchange, and a material is mainly used, wherein one side of the organic ligand used in this case is thiol or amine and the other side of the organic ligand is carboxylate or ammonium salt. FIG. 2 is an exemplary diagram depicting a method for substituting a representative organic ligand during the semiconductor quantum dots synthesis.

In a conventional ligand exchange reaction well known as yet, the ligand structure is described as follows:

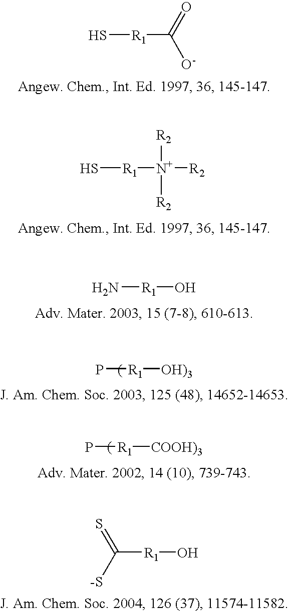

Although the ligand exchange reaction method is a simple method to disperse the quantum dots in various solvents, there is a problem that intrinsic light emission properties of the quantum dots are drastically reduced in a process of performing such exchange reaction.

In order to overcome this problem, a method for coating a semiconducting material having an energy bandgap being higher than that of the core quantum dot on the surface of the core quantum dot has been studied. This bandgap engineering obtains the core-sell quantum dots with maintaining a high light luminescence after the ligand exchange reaction; and, thus, an optical stability of the core quantum dots is dramatically increased.

On the other hand, there has been an intensively studied method for stabilizing a cadmium selenide (CdSe) as a representative of II-VI semiconductor quantum dots emitting a light within a visible ray region by using an inorganic semiconductor. In a process of coating a surface of CdSe core quantum dot, CdS, ZnS and ZnSe as a type of the II-VI semiconductor are mainly used. The ZnS Shell among those semiconductors is generally used for a core CdSe capping because an optical stability of CdSe can be maintained even under surface ligand exchange condition.

In a “SHELL GROWING METHOD THEORY” excess reactants used for core semiconductor quantum dots synthesis are removed before shell precursor addition. The shell precursors are added slowly into the core quantum dots solution at high temperature. At this time, a formation of a third nuclei is prevented only when the shell material having a small crystal lattice is slowly added into a core quantum dots solution (A graph illustrating a conventional crystal lattice value of the semiconductor quantum dot is shown in FIG. 3. It is advantageous that the semiconductor inorganic shell is grown along the lattice on the surface of the CdSe as the difference between the crystal lattice values is small in view of the CdSe as a reference).

A method of growing the shell passing through the purification process requires a long time as well as a many human power due to the purification process and the process of slowly adding a shell material, and there is a problem that a loss of large amount of materials is generated in a process of removing the non-reacted material in the reaction vessel. Also, there is a problem that organic metal chemical compound and dialkyl zinc generally used for growing the shell is expensive, and they are pyrophoric. Therefore, these cause the price to be raised, and also makes hindrance factors in producing the core-shell semiconductor quantum dots in large quantity.

Therefore, in order to overcome these problems and to achieve the mass production of the semiconductor quantum dots, a core semiconductor precursor and a shell semiconductor precursor which are low price as well as easily handled in the experimental condition are required, and various materials are developed in order to avoid handling of a dangerous organo-metallic compounds. And, alkyl salts or alkylphosphor acid cadmium salts are employed in order to synthesize a high quality core semiconductor quantum dots. And also, there is an attempt that a shell is formed by using alkyl acid zinc salts or alkylphosphor acid zinc salts for the core semiconductor quantum dots synthesized by various methods.

On the other hand, there is an attempt that the formation of shell is conducted by using the non-reacted materials existed in the solution without purifying the core semiconductor quantum dots solution. That is, after the CdSe is synthesized using an excessive amount of cadmium precursor, the CdSe/CdS is synthesized by blowing the H₂S gas into the non-reacted cadmium precursor remaining at the reaction vessel, and although a high quality semiconductor quantum dot having an excellent light emission property can be obtained through this method, the poisonous property of the used gas as well as the formation of the third nuclei are pointed as problems.

And also, after the core semiconductor quantum dots are synthesized by using an excessive amount of chalcogenide precursor as a similar method, there is an attempt that a shell is formed by adding another metal precursor without removing the non-reacted chalcogenide precursor remaining in the reaction vessel. In this case, although a stable metal material is used at a room temperature and a room pressure, since the used chalcogenide is dangerous and too reactive, there is also a problem that the stable metal material is slowly added to prevent new nuclei formation under the shell growth condition.

On the other hand, in the Korean Patent no. 10-0376403, although a method for manufacturing quantum dots having a II-IV group chemical compound semiconductor core and a II-IV group chemical compound semiconductor shell structure has been disclosed in order to represent a high light emission efficiency, since a diethyl zinc used for the semiconductor core manufacturing is unstable and very explosive and the chemical compound is added drop by drop during the manufacture of the semiconductor shell, it takes a long time and is very difficult to conduct. And also, there are problems that the reproducibility for the shell synthesis of the same thickness is difficult and the formation of new nuclei is inevitable.

### Disclosure

Technical Problem

It is, therefore, an object of the present invention to provide a method for synthesizing a high quality semiconductor quantum dots for a short time in large quantity through controlling a molecular structure, an amount and a reaction temperature of a chemical compound.

Other objects and advantages of the present invention is understood by following explanations and is more distinctly understood by embodiments of the present invention. And also, it is easily understood that the objects and the advantages of the present invention are easily realized by the means and the combination thereof claimed in following claims.

Technical Solution

In accordance with an aspect of the present invention, there is provided a method for mass producing semiconductor quantum dots, the method comprising the steps of: 1) synthesizing a central semiconductor quantum dot; and 2) after a group II metallic precursor with a band gap being larger than that of the central semiconductor quantum dots is added into a central semiconductor quantum dots solution at a room temperature, synthesizing the core-shell semiconductor quantum dots by raising and cooling a temperature of the core semiconductor quantum dots solution to a room temperature, wherein the step 1) includes the steps of: 1a) after a group II metallic precursor is melt, cooling the melted group II metallic precursor to a room temperature; 1b) after a surfactant is added, raising a temperature; and 1c) after a group IV chalcogenide precursor is added and reacted, cooling the temperature to the room temperature.

Advantageous Effects

In accordance with the present invention, the present invention can economically synthesize the quantum dots in a rapid time in a large quantity without an explosion. And, the present invention can be applied to the fields employing various luminous materials since the luminous semiconductor quantum dots synthesized by the present invention give emission at various wavelengths in the whole range of a visible ray with high luminous efficiency. And also, the present invention can be applied to a light emission device, a single electron transistor, a solar cell photo-sensitizer material and a bio-labelling tag since it is excellently stable in view of photochemistry and photphysics.

### DESCRIPTION OF DRAWINGS

The above and other objects and features of the present invention will become apparent from the following description of the preferred embodiments given in conjunction with the accompanying drawings, in which:

FIG. 1 is a schematic diagram representing a process for synthesizing semiconductor quantum dots using a Successive Injection of Precursor in One-Pot (SIPOP) in accordance with the present invention;

FIG. 2 is an exemplary diagram depicting a method for substituting representative organic ligands on the surface of semiconductor quantum dots for water-solublization of semiconductor quantum dots;

FIG. 3 is a graph illustrating a crystal lattice value of the semiconductor quantum dot;

FIG. 4 is an exemplary diagram showing a typical structure of the semiconductor quantum dot prepared in organic solution;

FIGS. 5 to 10 are transmission electron microscope image photographs of CdSe core semiconductor quantum dots obtained in accordance with a first to a sixth embodiments;

FIG. 11 is a transmission electron microscope image photograph and an energy dispersive X-ray spectrometer (EDX) analysis graph of CdSe/ZnSe core-shell semiconductor quantum dots obtained in accordance with a seventh embodiment (inset);

FIG. 12 is an absorption and emission spectra in accordance with the growth time of the CdSe core semiconductor quantum dots;

FIG. 13 is a graph representing the change of non-reacted Cd concentration in the reaction vessel during the synthesis of the CdSe core semiconductor quantum dots;

FIG. 14 is a high resolution electron microscope image photograph and an EDX analysis graph of the CdSe core semiconductor quantum dots and the CdSe/ZnSe core-shell semiconductor quantum dots(inset), wherein

A is CdSe core semiconductor quantum dots; and

B is CdSe/ZnSe core-shell semiconductor quantum dots;

FIG. 15 is an X-ray photoelectron spectroscopy (XPS) result graph of the CdSe core semiconductor quantum dots and the CdSe/ZnSe core-shell semiconductor quantum dots;

FIG. 16 is a concentration change graph of the Cd and Zn concentration during the ZnSe shell growth;

FIG. 17 is a transmission electron microscope image photograph of CdSe/ZnSe/ZnS core-doubleshell semiconductor quantum dots obtained in accordance with an eighth embodiment; and

FIG. 18 is a graph representing a light emission efficiency of the CdSe/ZnSe core-shell semiconductor quantum dots and the CdSe/ZnSe/ZnS core-doubleshell semiconductor quantum dots manufactured in accordance with the present invention.

### BEST MODE FOR THE INVENTION

Hereinafter, a method for synthesizing semiconductor quantum dots in large quantity in accordance with the present invention will be described in detail step by step.

The present invention is characterized in that it provides a method for synthesizing high luminous core-shell semiconductor quantum dots (hereinafter referred to quantum dots).

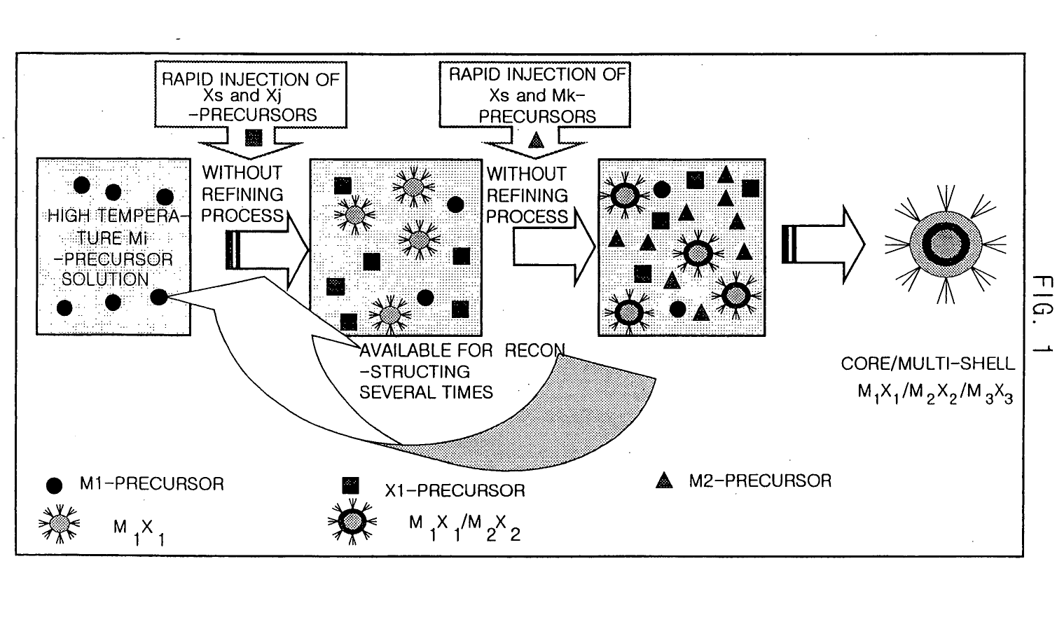

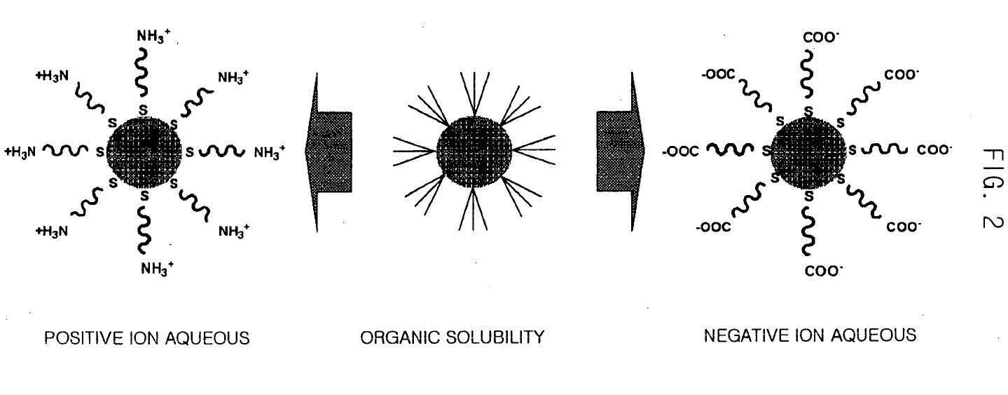

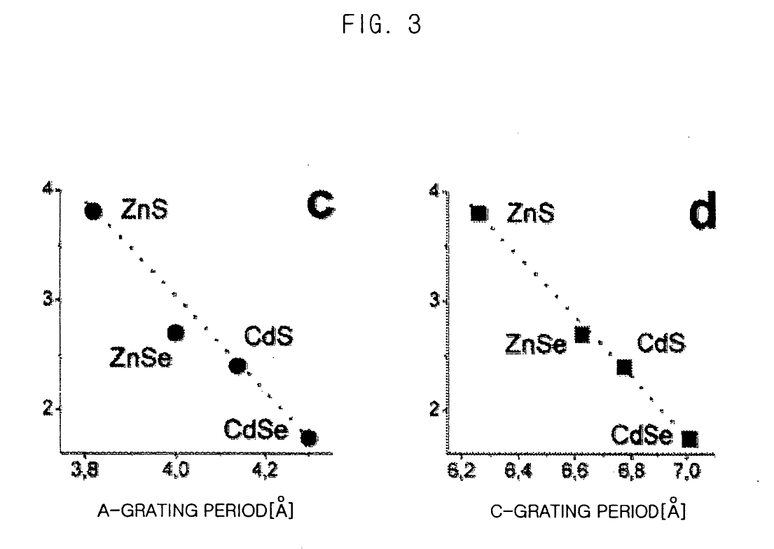

FIG. 1 is a schematic diagram representing a process for synthesizing semiconductor quantum dots in accordance with the present invention.

The method for synthesizing the quantum dots in accordance with the present invention includes a first step for synthesizing the core quantum dots, wherein the first step includes the steps of: 1a) after a group II metallic precursor is melt, cooling the melted group II metallic precursor to a room temperature; 1b) after a surfactant is added, raising a temperature; and 1c) after a group IV chalcogenide precursor is added and reacted, cooling the temperature to the room temperature.

In the present invention, although it is preferable that the group II metallic precursor used for synthesizing the core quantum dots in the step 1) is a material selected from a group of Cd, Zn and Hg and more preferable that the group II metallic precursor is one chemical compound selected from a group consisting of dimethyl cadmium (CdMe₂), cadmium oxide (CdO), cadmium carbonate (CdCO₃), cadmium acetate dihydrate (Cd(AC)₂.2H₂O), cadmium chloride (CdCl₂), cadmium nitrate (Cd(NO₃)₂), cadmium sulfate (Cd(SO₄)₂), zinc oxide (ZnO), zinc carbonate (ZnCO₃), zinc acetate (Zn(Ac)₂), mercury oxide (Hg₂O), mercury carbonate (HgCO₃) and mercury acetate (Hg(Ac)₂), any compound including the group II metal such as cadmium, zinc or mercury can be used as the group II metallic precursor without a limitation.

In the step 1), after the group II metallic precursor is melted, it is passed through a step of cooling down to a room temperature. At this time, preferably it is melted at a temperature ranging from approximately 150° C. to approximately 350° C. to form a transparent solution state. After such transparent solution is formed, it is again cooled down since it is difficult or takes a long time to make the transparent solution by reacting the metallic compound with the added surfactant if all reacting materials are added at the initial time and a vessel temperature increases. Also, it is to previously prevent a safety problem or an accident due to a high temperature vessel during a process of adding materials such as the surfactant.

Like this, it is preferable that the surfactant is added to play a role of stabilizing the metal ions after it is cooled down, and although the surfactant can be at least one material selected from a group consisting of tri-n-octylphosphine oxide, decylamine, didecylamine, tridecylamine, tetradecylamine, pentadecylamine, hexadecylamine, octadecylamine, undecylamin, dioctadecylamine, n,n-dimethyldecylamine, n,n-dimethyldodecylamine, n,n-dimethylhexadecylamine, n,n-dimethyltetradecylamine), n,n-dimethyltridecylamine, n,n-dimethylundecylamine, N-decylamine, N-methyloctadecylamine, didodecylamine, tridodecylamine, cyclododecylamine, N-methyldodecylamine, trioctylamine or the like, but a surfactant including a long chain such as an alkyl chain or an alkyne chain including at least carbon number 5 can be used in above described steps without any limitation.

Further, it can be used by diluting the surfactant using at least one solvent selected from a group consisting of 1-nonadecene, 1-octadecene, cis-2-methyl-7-octadecene, 1-heptadecene, 1-hexadecene, 1-pentadecene, 1-tetradecene, 1-tridecene, 1-undecene, 1-dodecene, 1-decene or the like.

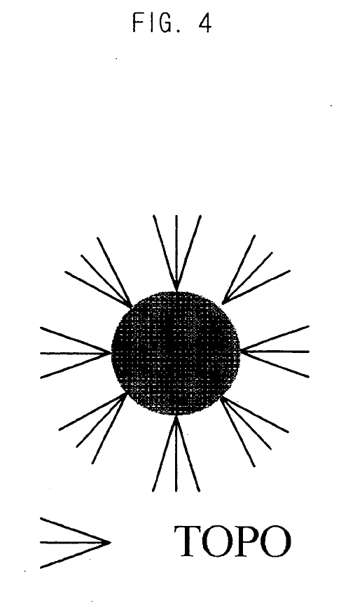

After the surfactant is added, it is preferable that the reaction temperature is raised to a temperature ranging from approximately 150° C. to approximately 350° C. since a decomposition phenomena of metallic salt is detected at a temperature being higher than 350° C. and the formation of nuclei having a luminous, characteristic can not be detected although it is observed for a long time at a temperature being lower than 150° C. Like this, if the surfactant is added to the group II metallic-precursor, a long alkyl chain is formed at a core quantum dot and, as a result, a dispersion characteristic is improved by this in an organic solvent. A conventional exemplary diagram of core quantum dots formed thereon the alkyl chain is represented in FIG. 4.

On the other hand, it is preferable that a group IV chalcogenide precursor used in the step 1) for synthesizing the core quantum dots is a material selected from a group consisting of sulfide (S), selenium (Se), tellurium (Te) and polonium (Po), although it is further preferable that a material is added in any compound selected from a group consisting of tri-n-alkylphosphine sulfide, tri-n-alkenylphosphine sulfide, alkylamino sulfide, alkenylamino sulfide, tri-n-alkylphosphine selenide, tri-n-alkenylphosphine selenide, alkylamino selenide, alkenylamino selenide, tri-n-alkylphosphine telluride, tri-n-alkenylphosphine telluride; alkylamino telluride, alkenylamino telluride, tri-n-alkylphosphine polluride, tri-n-alkenylphosphine polluride, alkylamino polluride, alkenylamino polluride; but a material including one of sulfide (S), selenium (Se), tellurium (Te) and polonium (Po) as a type of group IV chalcogenide element can be used in above described steps without any limitation.

It is preferable that an amount of group IV chalcogenide precursor is added more, particularly more 5 times than that of the group II metallic precursor, than that of the group II metallic precursor; and, preferably, a reaction of the group IV chalcogenide is performed during more than 3 minutes after the group IV chalcogenide is added, since the size of the CdSe does not become to be constant if the reaction time is below 3 minutes. If an amount of the group IV chalcogenide precursor is excessively added more than that of the group II metallic precursor, particularly more 5 times than that of the group II metallic precursor, there is an advantage, e.g., a reaction time saving or simplified convenient steps for synthesizing quantum dots, because the metallic precursor to be used for the shell is only added without adding the group IV chalcogenide precursor at the step 2) as the following quantum dot shell synthesizing step. That is, in a conventional quantum dots synthesizing method, when a shell is formed after core quantum dots are synthesized, a process of purifying the formed core quantum dots in order to supplementary add the chemical compound used for the shell. However, in the present invention, a man power and a time are saved by excluding a process of purifying the core quantum through adding an excessive amount of the group IV chalcogenide precursor being more 5 times than that of the metallic precursor in the step 1) and, also, a loss of final quantum dots which is avoidable during above purifying process can be prevented.

Like this, after the group IV chalcogenide precursor is added and reacted, it is preferable that it is cooled down to the room temperature. Generally, in the process of forming the shell, new third nuclei are always formed. However, if it is cooled down to the room temperature before shell is formed and then slow heated up like the present invention, the generation of the third nuclear is completely suppressed.

And also, when the group II metallic precursor is melted at the step 1), a fatty acid can be supplementary added. Like this, there is an advantage that the metallic precursor can be stabilized if the fatty acid is added. Though it is preferable that the fatty acid is at least one material selected from a group consisting of stearic acid, oleic acid, lauric acid, tetradecylphosphonic acid, hexadecylphosphonic acid, octadecylphosphonic acid, a surfactant including a long chain such as an alkyl chain, an alkyne chain or the like with at least five carbon number can be used as the fatty acid without any limitation.

Meanwhile, the group II metallic precursor used in the step 2) for synthesizing the shell of a semiconductor quantum dot production process is a material having larger bandgap than the core quantum dot; and, more particularly, zinc is preferable. Although it is further preferable that it is added in any chemical compound shape selected from a group consisting of zinc acetate, zinc undecylenate, zinc stearate, zinc oleate, a zinc salt including a long chain such as an alkyl chain, an alkyne chain or the like having at least carbon number 5 can be used as the group II metallic precursor without any limitation.

As described above, it is characterized in that the group IV chalcogenide precursor does not need to be added in the step 2) of the quantum dot manufacturing method in accordance with the present invention because lots of the group VI charcogenide precursor is remained in the reaction vessel after the core quantum dots synthesis, but only the metallic precursor is added at the room temperature. Like this, after the material is added at the room temperature, if the temperature is gradually raised, the shell is slowly grown and the formation of a new nuclear is completely suppressed. Moreover, in the event, there is an advantage that the ZnSe shells with the same thickness can be always manufactured by allowing all of the group IV chalcogenide precursors to be taken part in the ZnSe shell formation without uselessly wasting the group IV chalcbgenide precursor in the solution.

And also, in the prior art, there is a problem that it takes a long overall time by adding drop by drop when the shell chemical compound is added, whereas since there is no limitation in speed when the metallic precursor of the step 2) is added, in the present invention, there is an advantage that the time is saved.

Like this, after the metallic precursor is injected at the room temperature, it is maintained longer than 30 minutes at a temperature ranging from approximately 150° C. to approximately 350° C. If the temperature is lower than 150° C., the shell is not formed, and if the temperature is higher than 350° C., it is preferable that the metallic precursor is injected at the temperature ranging from 150° C. to 350° C. since there are problems that the size distribution of the particles is diverged and new particles are formed. And also, if the reaction is performed below 30 minutes, since the reaction does not occur, it is preferable that the reaction is performed for 30 minutes at the lowest.

On the other hand, in the method for synthesizing the quantum dots in accordance with the present invention, a process for manufacturing core-multishell quantum dots can be additionally added. That is, a sulfide precursor is additionally added to a solution of the core-shell semiconductor quantum dots formed at the step 2) in the room temperature, after it is maintained longer than 30 minutes at the temperature ranging from 150° C. to 350° C., and the core-multishell semiconductor quantum dots can be finally synthesized by cooling down to the room temperature. Although it is preferable that the sulfide precursor is added in a shape of any material selected from a group consisting of trialkylphosphine sulfide, trialkenylphosphine sulfide, bis(trimethylsilyl)sulfide, alkyl amino sulfide and alkenylamino sulfide, but it can be used without limit if a material contains sulfide.

On the other hand, in the method of synthesizing the quantum dots of the present. invention, a step of substituting an organic ligand to the core-shell quantum dots or the core/multi-shell quantum dots can be additionally added so as to be dispersed in various solvents.

The organic ligand to be used in the present invention is Xₓ(Y)ₙZ_{z}, wherein X is SH, NH₂, P, O═P or CSSH. The Z is OH, NH₂, NH₃⁺, COOH or PO₃²⁻. (Y)ₙ is a material mainly having a structure of an alkyl chain, an alkenyl chain or an aryl as a part to connect X and Y, it is preferable that a particularly usable material is any material selected from a group consisting of mercapto-alkyl acid, mercapto-alknenyl acid, mercapto-alkyl amine, mercapto-alkenyl amine, mercapto-alkyl alcohol, mercapto-alknenyl alcohol, dihydrolipoic acid, alkylamino acid, alkenylamino acid, aminoalkylcarboic acid, aminoalkenylcarboic acid, hydroxyalkylcarboic acid and hydroxyalkenylcarboic acid, but it is not limited to these materials and various types of organic ligands used to those skilled in the art can be used.

Although it is preferable that the size of the semiconductor quantum dots synthesized in accordance with the present invention is below 10 nm, but there is no limitation on the size thereof.

Hereinafter, the present invention will be described in detail with reference to embodiments.

However, the following described embodiments only exemplify the subject matter of the present invention; and the contents of the present invention are not limited to the following described embodiments.

### First Embodiment

### Manufacturing 1 of CdSe Core Quantum Dots

The cadmium oxide (CdO) of 51.4 mg (0.4 mmol) and the stearic acid of 230 mg (0.8 mmol) are added into a 50 mL round bottom flask and melted at a temperature of 300° C. If a transparent solution is formed, a temperature of the reaction vessel is cooled down to the room temperature. In this reaction vessel, tri-n-octylphosphine oxide (TOPO) of 2 g and hexa-decylamine (HDA) of 2 g are added and the temperature of the reaction vessel is raised to 300° C. Herein, 0.4M tri-n-octylphosphine selenides(TOPSe) of 5 mL is rapidly injected into the reaction vessel. After the CdSe is grown during a predetermined time, the temperature of the reaction vessel is cooled down to the room temperature.

### Second Embodiment

### Manufacturing 2 of CdSe Core Quantum Dots

The cadmium carbonate(CdCO₃) of 68.9 mg (0.4 mmol) and the stearic acid of 230 mg (0.8 mmol) are added into a 50 mL round bottom flask and melted at a temperature of 300° C. If a transparent solution is formed, a temperature of the reaction vessel is cooled down to the room temperature. In this reaction vessel, TOPO of 2 g and HDA of 2 g are added and the temperature of the reaction vessel is raised to 300° C. Herein, 0.4M tri-n-butylphosphine selenides(TBPSe) of 5 mL is rapidly injected into the reaction vessel. After the CdSe is grown during a predetermined time, the temperature of the reaction vessel is cooled down to the room temperature.

### Third Embodiment

### Manufacturing 3 of CdSe Core Quantum Dots

The cadmium oxide(CdO) of 51.4 mg (0.4 mmol) and the hexadecylphosphonic acid 130 mg (0.4 mmol) are-added into a 50 mL round bottom flask of 50 mL and melted at a temperature of 300° C. If a transparent solution is formed, a temperature of the reaction vessel is cooled down to the room temperature. In this reaction vessel, TOPO of 2 g and HDA of 2 g are added and the temperature of the reaction vessel is raised to 300° C. Herein, 0.4M tri-n-octylphosphine selenides(TOPSe) of 5 mL is rapidly injected into the reaction vessel. After the CdSe is grown during a predetermined time, the temperature of the reaction vessel is cooled down to the room temperature.

### Fourth Embodiment

### Manufacturing 4 of CdSe Core Quantum Dots

The cadmium acetate dihydrate(Cd(AC)₂.2H₂O) of 110 mg (0.4 mmol) and the hexadecylphosphonic acid 130 mg (0.4 mmol) are added into a 50 mL round bottom flask of 50 mL and melted at a temperature of 300° C. If a transparent solution is formed, a temperature of the reaction vessel is cooled down to the room temperature. In this reaction vessel, TOPO of 2 g and HDA of 2 g are added and the temperature of the reaction vessel is raised to 300° C. Herein, 0.4M tri-n-octylphosphine selenides(TOPSe) of 5 mL is rapidly injected into the reaction vessel. After the CdSe is grown during a predetermined time, the temperature of the reaction vessel is cooled down to the room temperature.

### Fifth Embodiment

### Manufacturing 5 of CdSe Core Quantum Dots

The cadmium oxide(CdO) of 51.4 mg (0.4 mmol) and the oleic acid 0.5 mL (excess) are added into a 50 mL round bottom flask of 50 mL and melted at a temperature of 300° C. If a transparent solution is formed, a temperature of the reaction vessel is cooled down to the room temperature. In this reaction vessel, TOPO of 2 g, HDA of 2 g and 1-octadecene of 5 mL are added and the temperature of the reaction vessel is raised to 300° C. Herein, 0.4M tri-n-butylphosphine selenides(TBPSe) of 5 mL is rapidly injected into the reaction vessel. After the CdSe is grown during a predetermined time, the temperature of the reaction vessel is cooled down to the room temperature.

### Sixth Embodiment

### Manufacturing 6 of CdSe Core Quantum dots

The cadmium oxide(CdO) of 51.4 mg (0.4 mmol) and the oleic acid 0.5 mL(excess) are added into a 50 mL round bottom flask of 50 mL and melted at a temperature of 300° C. If a transparent solution is formed, a temperature of the reaction vessel is cooled down to the room temperature. In this reaction vessel, 1-octadecene of 5 mL is added and the temperature of the reaction vessel is raised to 300° C. Herein, 0.4M tri-n-octylphosphine selenides(TOPSe) of 5 mL is rapidly injected into the reaction vessel. After the CdSe is grown during a predetermined time, the temperature of the reaction vessel is cooled down to the room temperature.

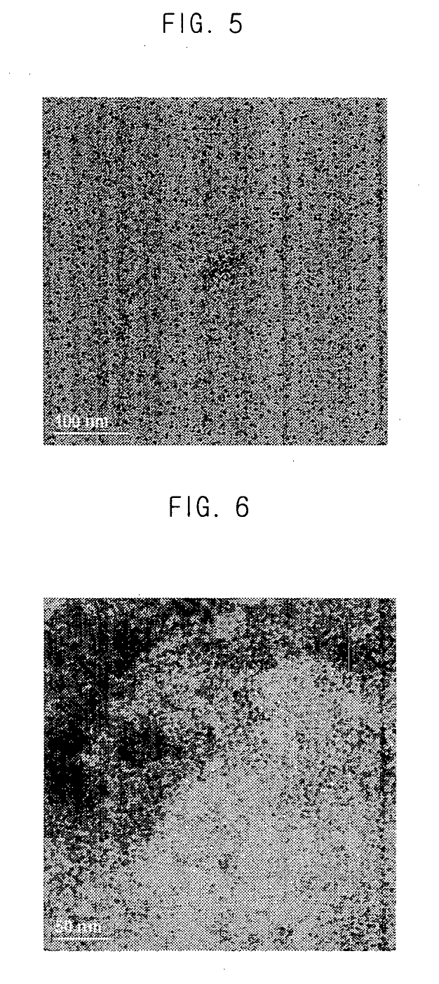

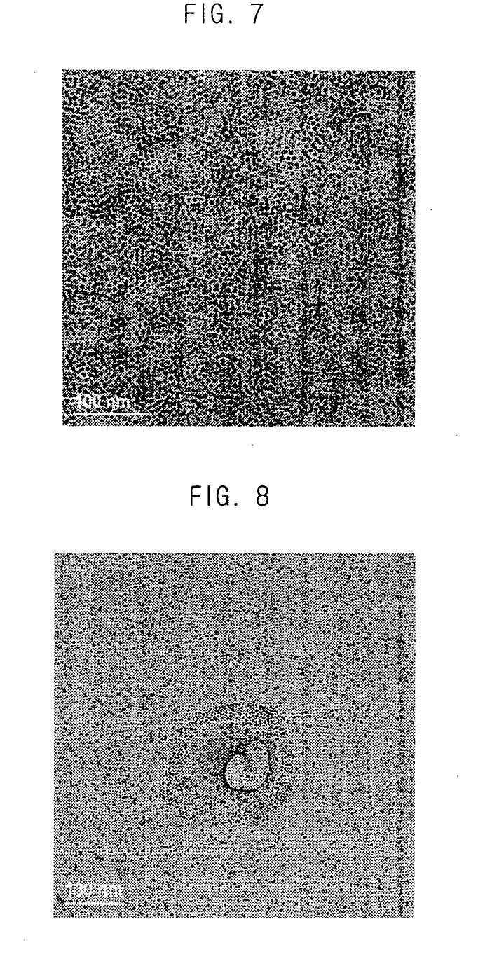

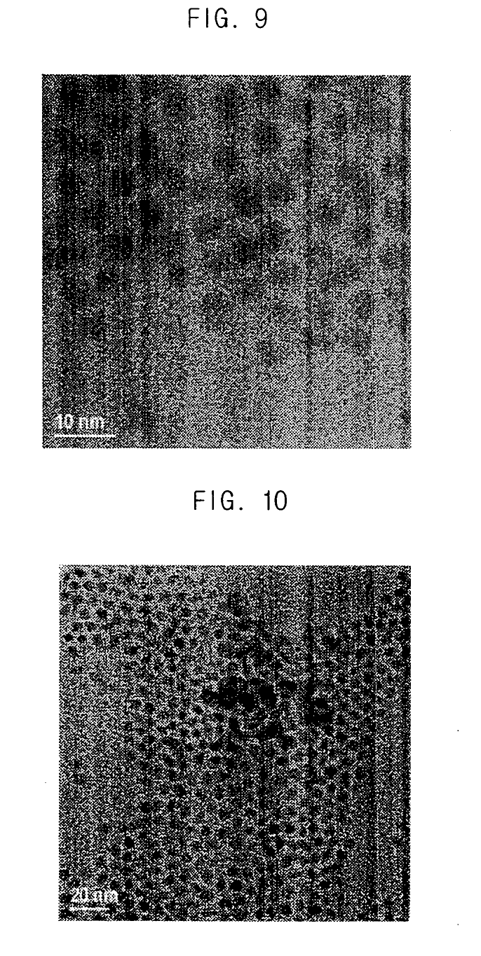

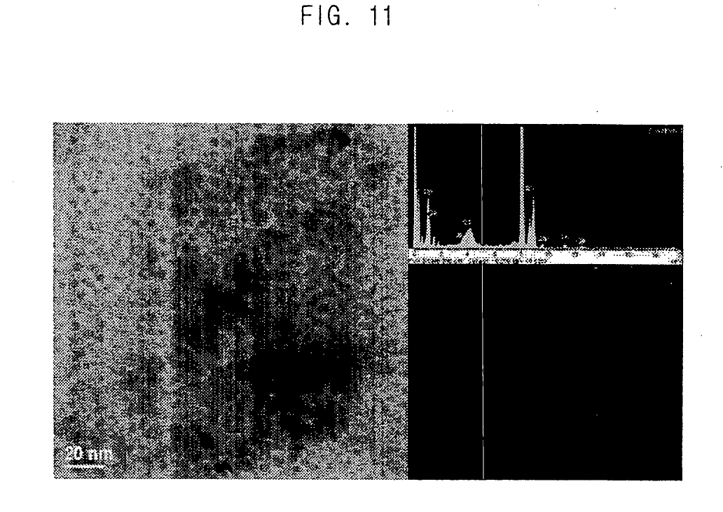

FIGS. 5 to 10 are transmission electro microscope image photographs of CdSe core semiconductor quantum dots obtained in accordance with a first to a sixth embodiments, and Wurtzite structure is identified by a result obtained by observing the crystallographic characteristics of the acquired core quantum dots through the transmission electron microscope and the powder XRD(X-ray diffraction).

### Seventh Embodiment

### Synthesizing CdSe/ZnSe Core-Shell Quantum Dots

A solution obtained by solving zinc stearate of 1 mmol di-n-octylamine of 10 mL is rapidly injected into each of the reaction vessels of the first to the sixth embodiments. After the temperature is raised to 200° C. and maintained for one hour, the temperature of the reaction vessel is cooled down to the room temperature. The CdSe/ZnSe core-shell quantum dots are acquired by recovering the core-shell semiconductor quantum dots using a toluene/methanol solvent/non-solvent pair.

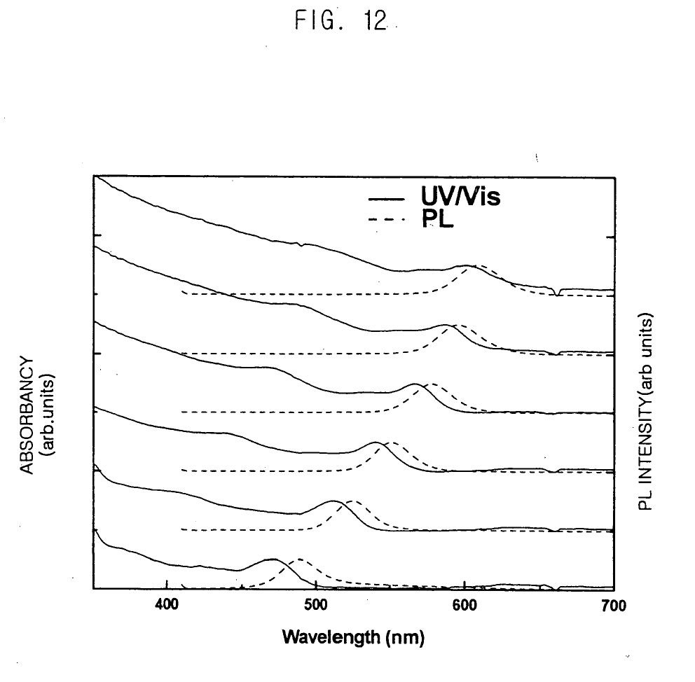

FIG. 11 is a transmission electro microscope image photograph and an energy dispersive X-ray spectrometer (EDX) analysis graph of the CdSe/ZnSe core-shell semiconductor quantum dots obtained in accordance with the above embodiment. Referring to FIG. 11, Zn can be identified and it is identified that the shell is formed.

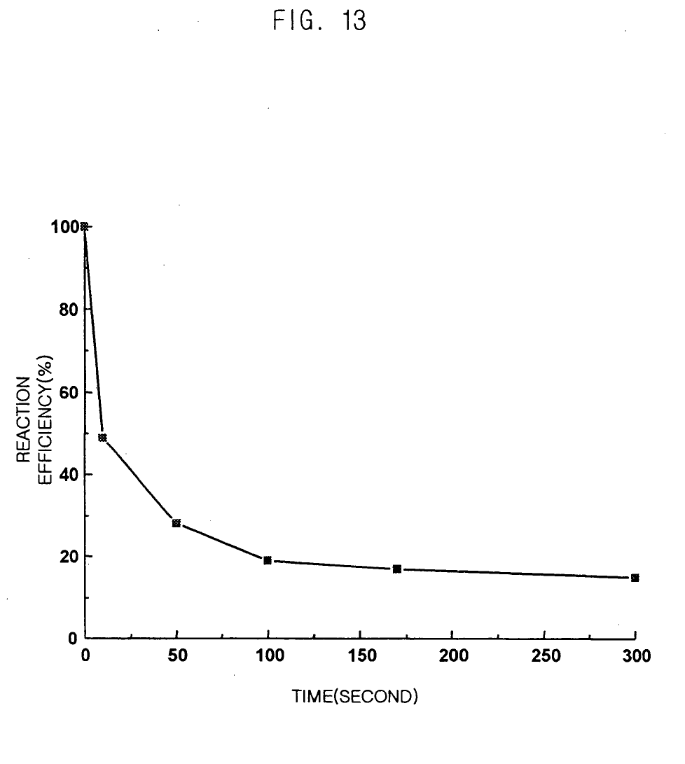

Absorption and emission spectra in accordance with the time of CdSe/ZnSe core-shell quantum dots are measured and the result is represented in FIG. 12. Referring to FIG. 12, it is identified that the absorption and emission spectra are changed according to the pass of the response time.

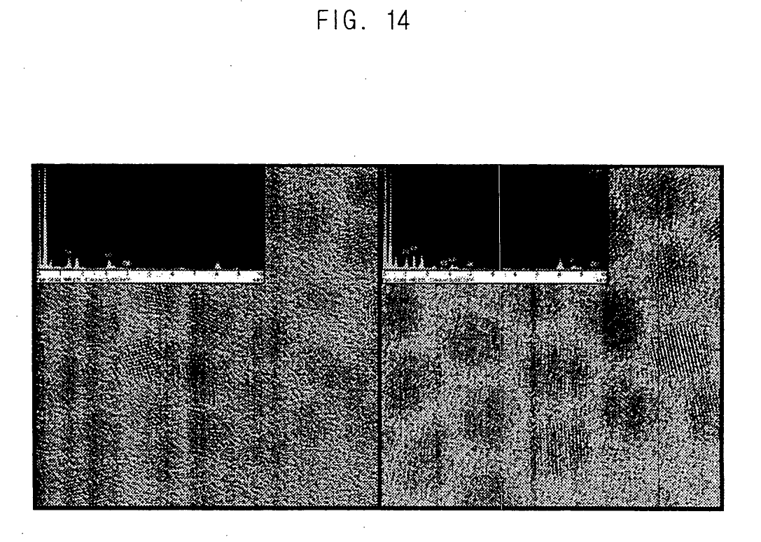

The change of Cd concentration in the reaction vessel during the synthesis of the CdSe/ZnSe core-shell quantum dots is observed and the result is represented in FIG. 13. Referring to FIG. 13, it is identified that the Cd concentration is reduced according to the time after the Se precursor is injected into a high temperature surfactant containing the Cd.

FIG. 14 is a high resolution electro microscope image photograph and an EDX analysis graph of the CdSe/ZnSe core-shell semiconductor quantum dots. It is identified that the size increases as the shell of ZnSe is formed.

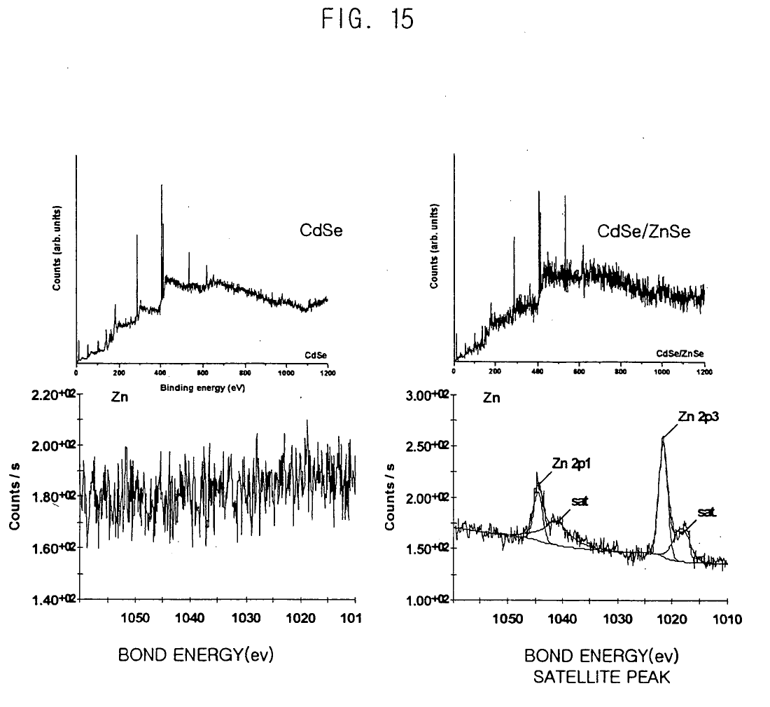

FIG. 15 is an X-ray photoelectron spectroscopy (XPS) result graph of the CdSe/ZnSe core-shell semiconductor quantum dots. The peak of Zn is detected at the XPS when it has the ZnSe shell.

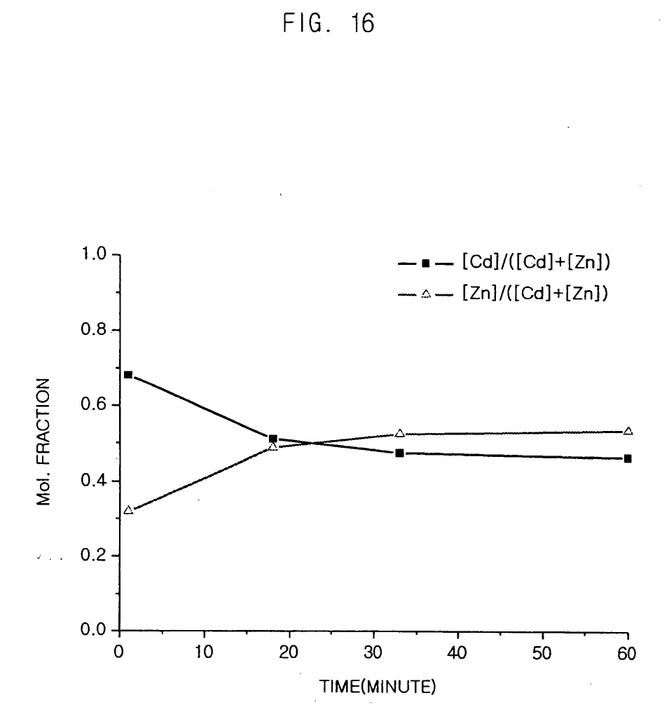

FIG. 16 is a concentration change graph of the changing Cd and Zn during the ZnSe shell formation.

### Eighth Embodiment

### Synthesizing CdSe/ZnSe/ZnS core-Doubleshell Quantum Dots

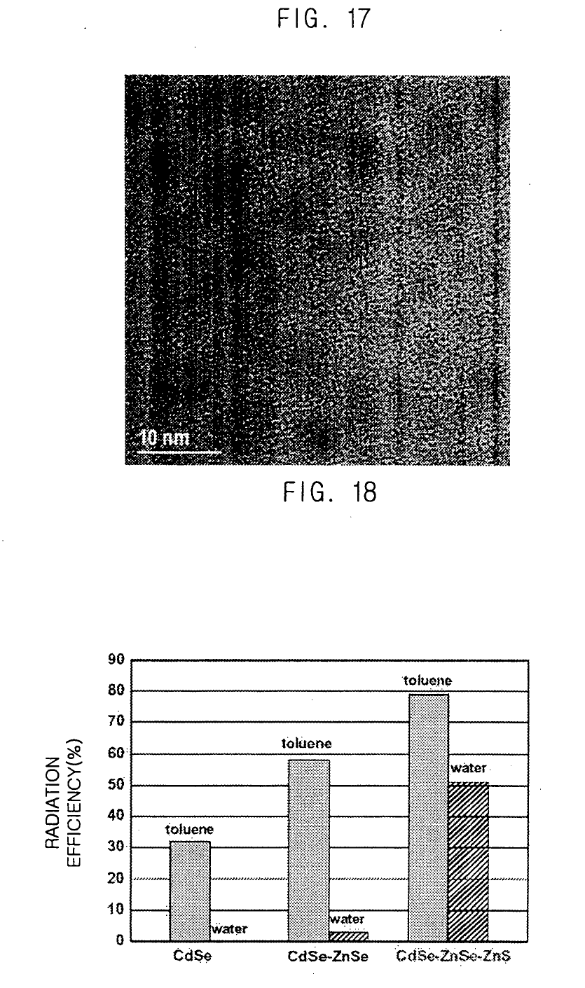

A solution obtained by solving bis(trimethylsilyl)sulfide of 0.25 mL into tri-n-octylphosphine of 5 mL is rapidly injected into the reaction vessel of the seventh embodiment. After the temperature is raised to 200° C. and maintained for one hour, the temperature of the reaction vessel is cooled down to the room temperature. The CdSe/ZnSe/ZnS core-doubleshell quantum dots is acquired by recovering the core-shell semiconductor quantum dots using a toluene/methanol solvent/non-solvent pair. An obtained transmission electro microscope image photograph of CdSe/ZnSe/ZnS core-doubleshell semiconductor quantum dot is represented in FIG. 17.

### Ninth Embodiment

### Ligand Substitution Reaction for CdSe/ZnSe Core-Shell Quantum Dots

Semiconductor quantum dots of the core-shell structure synthesized through the seventh embodiment are deposited by using a toluene/methanol solvent/non-solvent pair. After the semiconductor quantum dots are separated from the solvent using a high speed centrifugation method, it is solved in the toluene of 10 mL. An aminoethanethiol-HCl(AET-HCL) methanol solution of 100 mg (10 mL) is immersed into the toluene and boiled for 24 hours. After the reaction, only the quantum dots are recovered through the high speed centrifugation method. The acquired semiconductor quantum dot has an excellent solubility for the water.

### Tenth Embodiment

### Ligand Substitution Reaction for CdSe/ZnSe/ZnS Core-Doubleshell Quantum Dots

A semiconductor quantum dot of the core-doubleshell structure synthesized through the eighth embodiment is deposited by using a toluene/methanol solvent/non-solvent pair. After the semiconductor quantum dot is solved into chloroform of 10 mL, 3-mercaptopropionic acid of 0.5 mL is added. It is slowly agitated at the nitrogen atmosphere and at 60° C. for one day, and the deposition material is removed through the centrifugation method. The deposition material is dispersed into the water by inputting NH₄OH into the deposition material.

### Eleventh Embodiment

### Measuring the Light Emission Efficiencies of the CdSe/ZnSe Core-Shell Quantum Dot and the CdSe/ZnSe/ZnS Core-Doubleshell Quantum Dots

The light emission efficiencies of the CdSe/ZnSe core-shell quantum dot and the CdSe/ZnSe/ZnS core-doubleshell quantum dots manufactured in accordance with the present invention are measured at toluene and water, respectively. In order to disperse the quantum dot into the water, the surface is processed by using a 3-mercaptopropyl acid (MPA).

The light emission efficiency is observed by taking a picture of the light emission at a practical visual ray region during the radiation of ultraviolet ray with a 365 nm wavelength, and the observed result is represented in FIG. 18. Referring to FIG. 18, the light emission efficiency of the core-shell semiconductor quantum dots and the core-double shell semiconductor quantum dots manufactured in accordance with the present invention is very high in comparison with that of the CdSe core quantum dots.

While the present invention has been described with respect to certain preferred embodiments, it will be apparent to those skilled in the art that various changes and modifications may be made without departing from the scope of the invention as defined in the following claims.

What is claimed is:

1. A method for mass producing semiconductor quantum dots, the method comprising the steps of:
1) synthesizing a central semiconductor quantum dot; and
2) after a group II metallic precursor with a bandgap being larger than that of the central semiconductor quantum dot is added into a central semiconductor quantum dot solution at a room temperature, synthesizing the core-shell semiconductor quantum dots by raising and cooling a temperature of the central semiconductor quantum dot solution to a room temperature,
wherein the step 1) includes the steps of:
1a) after a group II metallic precursor is melt, cooling the melted group II metallic precursor to a room temperature;
1b) after a surfactant is added, raising a temperature; and
1c) after a group IV chalcogenide precursor is added and reacted, cooling the temperature to the room temperature.

2. A method as recited in claim 1, wherein the group II metallic precursor is selected from a group consisting of zinc, cadmium, mercury or the like.

3. The method as recited in claim 1, wherein in the step 1a) the group II metallic precursor is melted at a temperature ranging from 150° C. to 350° C.

4. The method as recited in claim 1, wherein the surfactant is at least one selected from a group consisting of tri-n-octylphosphine oxide, decylamine, didecylamine, tridecylamine, tetradecylamine, pentadecylamine, hexadecylamine, octadecylamine, undecylamin, dioctadecylamine, n,n-dimethyldecylamine, n,n-dimethyidodecylamine, n,n-dimethylhexadecylamine, n,n-dimethyltetradecylamine, n,n-dimethyltridecylamine, n,n-dimethylundecylamine, N-decylamine, N-methyloctadecylamine, didodecylamine, tridodecylamine, cyclododecylamine), N-methyldodecylamine and trioctylamine.

5. The method as recited in claim 1, wherein in the step 1b) the temperature is raised at a temperature ranging from 150° C. to 350° C.

6. The method as recited in claim 1, wherein the group IV chalcogenide precursor is selected from a group consisting of sulfur(S), selenium(Se), tellurium(Te), polonium(Po).

7. The method as recited in claim 1, wherein in the step 1c) after the group IV chalcogenide precursor is added, the reaction is performed during a time larger than 3 minutes.

8. The method as recited in claim 1, wherein a content ratio between group II metallic precursor and the group IV chalcogenide precursor is larger than 1:5 (mole ratio).

9. The method as recited in claim 1, wherein in the step 1) the melting is performed by additionally adding a fatty acid into group II metallic precursor.

10. The method as recited in claim 1, wherein the group II metallic precursor with the bandgap being larger than that of the central semiconductor quantum dot is zinc.

11. The method as recited in claim 1, wherein in the step 2) after the group II metallic precursor with the bandgap being larger than that of the core semiconductor quantum dot is added at the room temperature, it is maintained during a time approximately longer than 30 minutes by raising the temperature to a range of 150° C. to 350° C.

12. The method as recited in claim 1, in the step 2), additionally further comprises the following steps of:
adding the sulfur precursor into a core-shell semiconductor quantum dots solution in the room temperature; and
after it is maintained during a time approximately longer than 30 minutes at a temperature ranging from 150° C. to 350° C., manufacturing the central/shell semiconductor quantum dots by cooling to the room temperature.

13. The method as recited in claim 1, additionally further comprising the step of:
exchanging an organic ligand to the core-shell semiconductor quantum dots.

14. A method for mass producing semiconductor quantum dots, the method comprising the steps of:
1) synthesizing a central semiconductor quantum dot, wherein the step 1) includes the steps of:
1a) after a group II metallic precursor is melted at a temperature ranging from 150° C. to 350° C., cooling to a room temperature;
1b) after a surfactant is added, raising the room temperature to the temperature ranging from 150° C. to 350° C.; and
1c) after a group IV chalcogenide precursor is added and is reacted during a time approximately longer than 30 minutes, cooling the temperature to the room temperature;
2) after a group II metallic precursor with a bandgap being larger than that of the central semiconductor quantum dot is added into a core semiconductor quantum dot solution, synthesizing core-shell semiconductor quantum dots by raising the temperature to 150° C. to 350° C., maintaining during a time approximately larger than 30 minutes and dropping the temperature to the room temperature; and
3) exchanging an organic ligand to the central/shell semiconductor quantum dots.

15. A method for mass producing semiconductor quantum dots, the method comprising the steps of:
1) synthesizing a central semiconductor quantum dot, wherein the step 1) includes the steps of:
1a) after a group II metallic precursor is melted at a temperature ranging from 150° C. to 350° C., cooling to a room temperature;
1b) after a surfactant is added, raising the room temperature to the temperature ranging from 150° C. to 350° C.; and
1c) after a group IV chalcogenide precursor is added and is reacted during a time approximately longer than 30 minutes, cooling the temperature to the room temperature;
2) after a group II metallic precursor with a band gap being larger than that of the central semiconductor quantum dot is added into a central semiconductor quantum dots solution, synthesizing core/shell semiconductor quantum dots by raising the temperature to 150° C. to 350° C., maintaining during a time approximately larger than 30 minutes and dropping the temperature to the room temperature;
3) after the sulfur precursor is added into a central/shell semiconductor quantum dot solution at a temperature ranging from 150° C. to 350° C. and maintained during a time approximately longer than 30 minutes, synthesizing the central/shell semiconductor quantum dots by cooling to the room temperature; and
4) exchanging an organic ligand to the central/shell semiconductor quantum dots.
